(19) United States
(12) Patent Application Publication
(10) Pub. No.: US 2026/0242640 A1
(43) Pub. Date: Aug. 20, 2026

(54) ADHESIVE COMPOSITION AND CONNECTION STRUCTURE

(71) Applicant: Resonac Corporation, Tokyo (JP)

(72) Inventors: Takahiro FUKUTOMI, Tokyo (JP); Yuka ITOH, Tokyo (JP); Hiroyuki IZAWA, Tokyo (JP)

(21) Appl. No.: 19/479,759

(22) PCT Filed: Sep. 24, 2024
(86) PCT No.: PCT/JP2024/034005

§ 371 Date: Oct. 29, 2025

(30) Foreign Application Priority Data
Sep. 26, 2023 (JP) 2023-162681

(51) Int. Cl. C09J 9/02; H10W 72/00; H10W 72/30; H10W 72/40; H10W 72/90; H10W 90/00

(52) U.S. Cl. CPC C09J 9/02; H10W 72/07332; H10W 72/074; H10W 72/325; H10W 72/352; H10W 72/354; H10W 72/40; H10W 72/952; H10W 90/732; H10W 90/734

(57) ABSTRACT

An adhesive composition containing conductive particles each having a plurality of protrusions on a surface thereof, wherein the conductive particles have a compressive hardness of 350 kgf/mm² to 1500 kgf/mm² at 20% compression, and a proportion of an area of the plurality of protrusions to an area of the surface of each conductive particle is 30% or more.

### TECHNICAL FIELD

The present invention relates to an adhesive composition and a connection structure.

### BACKGROUND ART

In fields such as micro-OLEDs used for AR/VR applications, anisotropic conductive films are used to connect electronic components to fine circuit electrodes. Anisotropic conductive films include, for example, conductive particles dispersed in adhesive films. By interposing such an anisotropic conductive film between opposing electrodes and applying heat and pressure, the opposing electrodes can be electrically connected to each other while maintaining insulation between adjacent electrodes on the same substrate.

Various structures have been known for electrodes to be connected by anisotropic conductive films. For example, PTL 1 discloses a semiconductor device having a bump electrode with a two-layer structure including a first conductive layer and a second conductive layer formed on the first conductive layer, wherein the second conductive layer is made of a material having a lower hardness than the first conductive layer.

In anisotropic conductive films, conductive particles having protrusions on their surfaces may be used as the conductive particles. For example, PTL 1 discloses an adhesive composition containing an adhesive component and conductive particles, wherein the conductive particles each include a plastic particle and a metal layer coating the plastic particle and each have a plurality of protrusions on the surface thereof, the plurality of protrusions having an average height of 85 to 1200 nm.

### CITATION LIST

### Patent Literature

PTL 1: Japanese Unexamined Patent Application Publication No. 2000-286299
PTL 2: International Publication No. 2018/199329

### SUMMARY OF INVENTION

### Technical Problem

According to the inventors' investigations, it has been found that, when the electrode of at least one of two electronic members to be connected includes a relatively hard conductive layer (e.g., a Ni layer) and a relatively soft conductive layer (e.g., a Au layer) formed on the surface (the outermost surface of the electrode) of the hard conductive layer, and the soft conductive layer is thin, the connection resistance between the connected electronic members tends to increase upon prolonged exposure to high-temperature, high-humidity conditions (e.g., temperature 85° C. and humidity 85%), compared with when the soft conductive layer is thick. The adhesive composition is required to suppress an increase in resistance (exhibit good connection reliability) even when used for connecting such electronic members.

Accordingly, an object of an aspect of the present invention is to provide an adhesive composition that exhibits good connection reliability when used to connect electrodes having a thin and soft conductive layer at their outermost surfaces.

### Solution to Problem

As a result of investigations to solve the above issues, it has been found that, when the soft conductive layer at the electrode outermost surface is thick, the soft conductive layer deforms under the heat and pressure applied during mounting so as to conform to the shapes of the conductive particles, and the electrode and the conductive particles accordingly make contact over a large area, resulting in stable and good conductivity. In contrast, when the soft conductive layer at the electrode outermost surface is thin, the conductive layer is less likely to deform, the contact area between the electrode and the conductive particles is reduced, and this reduced contact area is one factor that tends to increase the connection resistance under high-temperature, high-humidity conditions.

Therefore, the inventors have attempted to reduce the compressive hardness of the conductive particles so that the conductive particles are flattened under pressure to increase the contact area between the electrode and the conductive particles. However, it has also been found that, if the compressive hardness of the conductive particles is too low, the protrusions of the conductive particles may fail to indent adequately into the electrode and may thus fail to provide good conductivity.

The inventors have conducted further intensive studies and have found that, by controlling the compressive hardness of the conductive particles and the proportion of the area of the protrusions of the conductive particles within particular ranges, it is possible to ensure an adequate contact area between the electrode and the conductive particles while allowing the protrusions of the conductive particles to indent adequately into the electrode surface. As a result, connection reliability under high-temperature, high-humidity conditions can be improved, completing the present invention.

In some aspects, the present invention provides [1] to [7] below.
[1] An adhesive composition containing: conductive particles each having a plurality of protrusions on a surface thereof, wherein the conductive particles have a compressive hardness of 350 kgf/mm² to 1500 kgf/mm² at 20% compression, and a proportion of an area of the plurality of protrusions to an area of the surface of each conductive particle is 30% or more.
[2] A connection structure including: a first electronic member having a first electrode; a second electronic member having a second electrode; and a connection portion disposed between the first electronic member and the second electronic member and electrically connecting the first electrode and the second electrode to each other, wherein the connection portion contains a cured product of the adhesive composition according to [1].
[3] The connection structure according to [2], wherein at least one of the first electrode and the second electrode includes a surface layer containing Au.
[4] The connection structure according to [3], wherein the surface layer has a thickness of 3 μm or less.
[5] A method for producing a connection structure, the method including: a step of placing the adhesive composition according to [1] between a first electronic member having a first electrode and a second electronic member having a second electrode; and a step of thermocompression-bonding the first electronic member and the second electronic member to each other with the adhesive composition interposed therebetween to electrically connect the first electrode and the second electrode to each other.
[6] The method for producing a connection structure according to [5], wherein at least one of the first electrode and the second electrode includes a surface layer containing Au.
[7] The method for producing a connection structure according to [6], wherein the surface layer has a thickness of 3 μm or less.

### Advantageous Effects of Invention

According to an aspect of the present invention, it is possible to provide an adhesive composition that exhibits good connection reliability when used to connect electrodes having a thin and soft conductive layer at their outermost surfaces.

### BRIEF DESCRIPTION OF DRAWINGS

FIG. 1 is a schematic cross-sectional view of one embodiment of an adhesive film.

FIG. 2 includes schematic cross-sectional views of embodiments of a conductive particle.

FIG. 3 is a schematic cross-sectional view of another embodiment of the adhesive film.

FIG. 4 is a schematic cross-sectional view of one embodiment of a connection structure.

FIG. 5 includes schematic cross-sectional views of one embodiment of a method for producing the connection structure.

### DESCRIPTION OF EMBODIMENTS

Embodiments of the present invention will be described below in detail with reference to the drawings as appropriate.

### <Adhesive Composition>

An adhesive composition according to an embodiment contains conductive particles each having a plurality of protrusions on a surface thereof. The conductive particles have a compressive hardness of 350 kgf/mm² to 1500 kgf/mm² at 20% compression, and the proportion of the area of the protrusions to the area of the surface of each conductive particle is 30% or more.

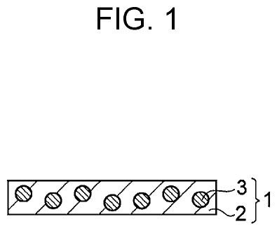

The adhesive composition typically further contains an adhesive component, and the conductive particles are dispersed in the adhesive component. The adhesive composition may be in paste form or in film form. FIG. 1 is a schematic cross-sectional view of one embodiment of a film-like adhesive composition (adhesive film). Referring to FIG. 1, in one embodiment, the adhesive film 1 is composed of a single layer including an adhesive component (insulating adhesive) 2 and conductive particles 3 dispersed in the adhesive component 2.

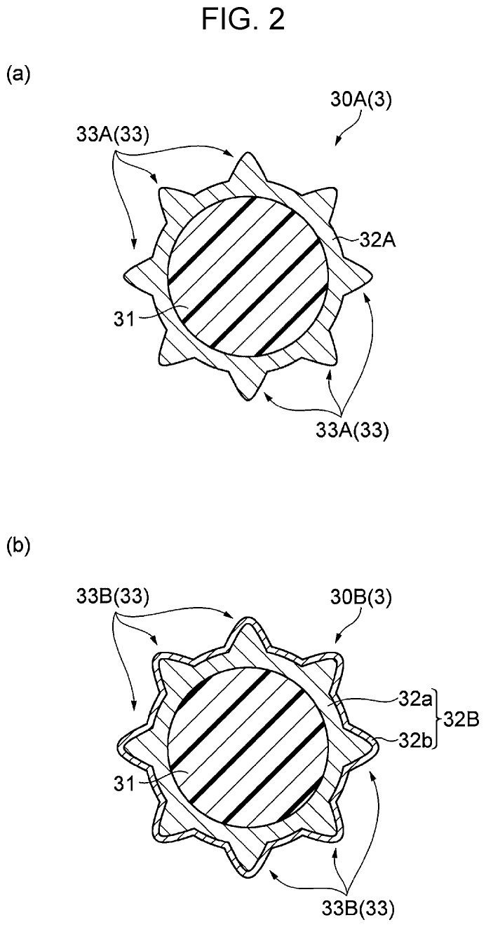

FIG. 2 includes schematic cross-sectional views of embodiments of a conductive particle 3. Referring to FIG. 2 (a), in one embodiment, a conductive particle 30A includes a non-conductive core 31 and a conductive layer 32A coating the core 31.

Preferably, the conductive layer 32A coats substantially the entire surface of the core 31. However, part of the surface of the core 31 may be exposed without being coated with the conductive layer 32A as long as the function of electrically connecting the electronic members is maintained.

The core 31 is formed of a non-conductive material, such as glass, ceramic, or resin, and is preferably formed of resin. Examples of the resin include acrylic resin, styrene resin, silicone resin, polybutadiene resin, and copolymers of monomers constituting these resins. The core 31 may be a particle containing a polymer including, as monomer units, at least one monomer selected from styrene and divinylbenzene. The polymer may further include (meth)acrylates as monomer units. The average diameter of the core 31 may be, for example, 1 μm or more, or 2 μm or more, and may be 40 μm or less, 30 μm or less, or 20 μm or less.

The conductive layer 32A is composed of, for example, a single conductive layer. The conductive layer 32A is formed of, for example, Ni, Cu, Ag, Ru, or Pd, or an alloy containing these metal elements. The alloy may be, for example, a Ni-containing alloy (Ni alloy). Examples of the Ni alloy include Ni—B, Ni—P, and Ni—W—B. To further suppress the reduction in connection reliability when the adhesive composition is used to connect electrodes having a thin and soft conductive layer at their outermost surfaces, the conductive layer 32A is preferably formed of Pd. The thickness of the conductive layer 32A may be, for example, 50 nm or more and may be 300 nm or less. The thickness of the conductive layer 32A refers to the thickness of a portion of the conductive layer where the protrusions described below are not formed. The thickness of the conductive layer 32A can be measured using an electron microscope.

Referring to FIG. 2 (b), a conductive layer 32B in a conductive particle 30B according to another embodiment may be composed of two layers: a first conductive layer 32a and a second conductive layer 32b. In other words, the conductive particle 30B according to another embodiment includes a core 31, the first conductive layer 32a coating the core 31, and the second conductive layer 32b coating the first conductive layer 32a.

The first conductive layer 32a is formed of Ni, for example. The second conductive layer 32b may be formed of Au or Pd, for example. In other words, the conductive particle 30B may have a Au or Pd layer on its outermost surface side as a conductive layer.

The thickness of the first conductive layer 32a may be, for example, 50 nm or more and may be 300 nm or less. The thickness of the second conductive layer 32b may be, for example, 2 nm or more, 5 nm or more, or 10 nm or more, and may be 200 nm or less, 100 nm or less, or 50 nm or less. The thickness of the first conductive layer 32a and the second conductive layer 32b refers to the thickness of a portion of the corresponding conductive layer where the protrusions described below are not formed. The thickness of the first conductive layer 32a and the second conductive layer 32b can be measured using an electron microscope.

A plurality of protrusions 33 are formed on the surface of the conductive particle 3. In the conductive particle 30A illustrated in FIG. 2 (a), the protrusions 33A are formed of the conductive layer 32A composed of a single layer. In the conductive particle 30B illustrated in FIG. 2 (b), the protrusions 33B are formed of the conductive layer 32B composed of two layers: the first conductive layer 32a and the second conductive layer 32b.

The proportion of the area of the plurality of protrusions 33 to the area of the surface of each conductive particle 3 (hereinafter also referred to as the “area fraction of the protrusions”) is 30% or more. To increase the contact area between the conductive particles and the electrode and further improve connection reliability, the area fraction of the protrusions may be 32% or more, 35% or more, 38% or more, or 40% or more. The area fraction of the protrusions may be 70% or less, 65% or less, 60% or less, or 55% or less.

The area fraction of the protrusions is determined by analyzing a black-and-white SEM image of the conductive particles 3 generated by imaging using a scanning electron microscope (SEM). The SEM image can be analyzed by using the method described in Japanese Unexamined Patent Application Publication No. 2016-61722. Specifically, the area fraction of the protrusions can be determined by using a method including: a step of detecting, in an SEM image in which a plurality of conductive particles 3 are imaged, the particle edge of each conductive particle 3, which is the boundary between the projected image of the corresponding conductive particle 3 and the other regions of the image; a step of calculating, from the intensity frequency distribution in the region inside each particle edge, a second threshold corresponding to the boundary between the protrusions and the other regions; a step of binarizing the region inside each particle edge using the obtained second threshold to generate a binary image; a step of calculating, as the area fraction of the protrusions of each conductive particle 3, the proportion of the area of the region corresponding to the protrusions to the area of the region inside each particle edge in the obtained binary image; and a step of calculating the average value of the area fractions of the protrusions for 100 conductive particles 3.

In the analysis of the SEM image described above, the particle edge substantially corresponds to the outer periphery of the two-dimensional projected image of each conductive particle 3, including the irregularities attributable to the protrusions. The intensity frequency distribution obtained from the SEM image typically exhibits a minimum associated with the particle edge portion. The SEM image is binarized using the intensity corresponding to this minimum as a first threshold to generate a binary image. The edge formed in the obtained binary image is detected as the particle edge. Based on the particle edge, the centroid coordinates of each conductive particle 3 in the SEM image are calculated. A circle fitted to each particle edge is determined by the least-squares method, the center of this circle is taken as the center coordinates of each conductive particle 3, and the radius r of this circle is obtained. The circular region having a radius of r/2 centered at the center coordinates is identified as the region inside the particle edge.

In the intensity frequency distribution of the region inside the particle edge, in general, the intensity values of pixels in the region obtained by combining the particle surface and the portion excluding the edges of the protrusions are mainly reflected on the low-intensity side, whereas the intensity values of pixels in the region of the edge portions of the protrusions are mainly reflected on the high-intensity side. Accordingly, a frequency peak representing the particle surface and the portion excluding the edges of the protrusions appears on the low-intensity side; whereas, on the high-intensity side, a region where the frequency exhibits the maximum rate of decrease appears, indicating that the particle surface and the portion excluding the edges of the protrusions rapidly diminish as the intensity increases. Based on this frequency distribution, the second threshold is selected from the range between the intensity value corresponding to the maximum frequency on the low-intensity side and the intensity value corresponding to the region where the frequency exhibits the maximum rate of decrease on the high-intensity side. More specifically, the intensity value intermediate between the intensity value corresponding to the maximum frequency on the low-intensity side and the intensity value corresponding to the point on the high-intensity side where the frequency exhibits the maximum rate of decrease is defined as the second threshold. Based on the second threshold, a binary image of the region inside the particle edge is generated, and the proportion of the area of the white region in the binary image to the area of the region inside the particle edge is calculated as the area fraction of the protrusions of each conductive particle 3.

The average height of the plurality of protrusions 33 may be 50 nm or more, 70 nm or more, 90 nm or more, 110 nm or more, or 130 nm or more, and may be 1200 nm or less, 1000 nm or less, 600 nm or less, 500 nm or less, 400 nm or less, 300 nm or less, 200 mm or less, or 150 nm or less.

The average height of the plurality of protrusions 33 can also be determined by analyzing the SEM image of the conductive particles according to the method described in Japanese Unexamined Patent Application Publication No. 2016-61722. Specifically, the average height of the protrusions 33 can be determined by using a method including: a step of detecting, in an SEM image in which a plurality of conductive particles 3 are imaged, the particle edge of each conductive particle 3, which is the boundary between the projected image of the corresponding conductive particle 3 and the other regions of the image; a step of calculating, based on the particle edge, the center coordinates of each conductive particle 3 in the SEM image; a step of dividing the particle edge into eighteen particle edge segments, each segment spanning 40 degrees and shifted by 20 degrees in the polar coordinates centered at the center coordinates, calculating, for each particle edge segment, the difference between a maximum and a minimum of the distance from the center coordinates to the particle edge, and calculating the average value of these differences as the average height of the protrusions 33; and a step of calculating the average height of the protrusions 33 for 100 conductive particles 3, and calculating their average value.

In the analysis of the SEM image described above, the maximum distance between the center coordinates and the particle edge for each particle edge segment is determined by selecting, among the points constituting the edge in each particle edge segment, the three largest distances from the center coordinates and taking the average value of these distances. The minimum distance between the center coordinates and the particle edge for each particle edge segment is determined by selecting, among the points constituting the edge in each particle edge segment, the three smallest distances from the center coordinates and taking the average value of these distances.

The average particle size of the conductive particles 3 may be 1.0 μm or more, 2.0 μm or more, 2.5 μm or more, 3.0 μm or more, or 3.2 μm or more, and may be 10 μm or less, 8.0 μm or less, 6.0 μm or less, 5.0 μm or less, or 4.0 μm or less. In this description, the average particle size is determined by measuring the particle sizes of any 300 (pcs) of the conductive particles 3 through observation using a scanning electron microscope (SEM) and taking the average value of the obtained particle sizes. More specifically, the average particle size of the conductive particles 3 is obtained by determining, in the SEM image of the conductive particles 3, a circle fitted to the particle edge of each conductive particle 3 by the least-squares method as described above, taking the diameter of the circle as the particle size of each conductive particle 3, and calculating the average value of the particle sizes of 300 conductive particles 3.

The compressive hardness of the conductive particles 3 at 20% compression is 350 kgf/mm² to 1500 kgf/mm². The compressive hardness of the conductive particles 3 at 20% compression may be 380 kgf/mm² or higher, 400 kgf/mm² or higher, 420 kgf/mm² or higher, or 450 kgf/mm² or higher, and may be 1300 kgf/mm² or less, 1200 kgf/mm² or less, 1100 kgf/mm² or less, 1000 kgf/mm² or less, 900 kgf/mm² or less, or 800 kgf/mm² or less. A higher compressive hardness of the conductive particles 3 is preferred because, when the adhesive composition is used as an anisotropic conductive adhesive composition, the protrusions of the conductive particles 3 more readily indent into the electrode surface. A lower compressive hardness of the conductive particles is preferred because, when the adhesive composition is used as an anisotropic conductive film, the conductive particles are more readily flattened, so that the contact area between the electrode and the conductive particles more easily increases.

The compressive hardness (hereinafter also referred to as “K value”) of the conductive particle 3 is measured using a surface hardness compression tester (e.g., HM2000 manufactured by Fischer Instruments K.K.). Specifically, first, the conductive particles 3 are scattered onto a slide glass (S1214 manufactured by Matsunami Glass Ind., Ltd.) on a stage set at 25° C. One conductive particle 3 is then selected from the scattered conductive particles 3, and the K value is determined from the stress-strain curve obtained by compressing the conductive particle 3 at a rate of 0.33 mN/s from the center from an initial load of 0.1 mN using a diamond indenter having a prismatic shape with a square base of 50 μm on a side. Specifically, using the compression equation for an elastic sphere:

$$F = ( {2}^{1 / 2} / 3 ) \times ( {S}^{3 / 2} ) \times ( E \times {R}^{1 / 2} ) / ( 1 - {σ}^{2} )$$

where F (N) denotes load, S (mm) denotes displacement, R (mm) denotes particle radius, E (Pa) denotes elastic modulus, and σ denotes Poisson's ratio, the K value can be obtained from the following equation:

$$K = E / ( 1 - {σ}^{2} ) = ( 3 / {2}^{1 / 2} ) \times F \times ( {S}^{- 3 / 2} ) \times ( {R}^{- 1 / 2} ) .$$

Furthermore, the K value at a given deformation rate can be determined from the following equation:

$$K = 3000 F / ( {D}^{2} \times {X}^{3 / 2} ) \times {10}^{6}$$

where X (%) denotes deformation rate, and D (μm) denotes sphere diameter. The deformation rate X is calculated from the following equation:

$$X = ( S / D ) \times 100.$$

The compressive hardness of the conductive particle 3 at 20% compression means the K value at a deformation rate X of 20%. The maximum test load in the compression test is set to 50 mN, for example.

The percent recovery of the conductive particles 3 may be 10% or more, 20% or more, 25% or more, or 30% or more, and may be 100% or less, 90% or less, 80% or less, 75% or less, or 70% or less.

The percent recovery of the conductive particle 3 is measured using a surface hardness compression tester (e.g., HM2000 manufactured by Fischer Instruments K.K.). Specifically, first, the conductive particles 3 are scattered onto a slide glass (S1214 manufactured by Matsunami Glass Ind., Ltd.) on a stage set at 25° C. One conductive particle 3 is then selected from the scattered conductive particles 3 and compressed from an initial load of 0.1 mN to a load of 5 mN at a rate of 0.33 mN/s from the center using a diamond indenter having a prismatic shape with a square base of 50 μm on a side, and the load is then reduced to the initial load at a rate of 0.33 mN/s. The percent recovery of the conductive particle 3 is calculated as the value of L1/L2×100(%), where L2 denotes the displacement of the conductive particle 3 from the point under the initial load (load 0.1 mN) to the load-reversal point (load 5 mN), and L1 denotes the displacement of the conductive particle 3 from the load-reversal point to the point under the final load (load 0.1 mN). This operation is performed for 10 conductive particles 3, and the average value is taken to calculate the percent recovery of the conductive particles 3 in this embodiment.

The conductive particles 3 having the protrusions as described above can be obtained, for example, by forming the conductive layers 32A and 32B on the surface of the core 31 by metal plating. The protrusions 33 can be formed by changing the plating conditions during metal plating to vary the thicknesses of the conductive layers 32A and 32B. For example, the protrusions 33 can be formed by increasing the concentration of the plating solution in a stepwise manner in the metal plating process.

Alternatively, a conductive layer having nodular protrusions can be formed by adjusting the pH of a plating solution, for example, by adjusting the pH of a nickel plating solution to 6 (see Mochizuki et al., Surface Technology, Vol. 48, No. 4, pp. 429-432, 1997). The use of glycine as a complexing agent contributing to the stability of the plating bath forms a conductive layer having a flat surface; whereas the use of tartaric acid or DL-malic acid as a complexing agent forms nodular protrusions (e.g., see Ogihara et al., Amorphous Plating, Vol. 36, pp. 35-37, 1994; Ogihara et al., The journal of Japan Institute for Interconnecting and Packaging Electronic Circuits, Vol. 10, No. 3, pp. 148-152, 1995). The conductive layers 32A and 32B having the protrusions 33 can be formed by using these methods.

To prepare the conductive particles 30B illustrated in FIG. 2 (b), for example, the second conductive layer 32b can be obtained by forming a Au or Pd layer by displacement plating after forming the first conductive layer 32a having protrusions by the above method.

The area fraction of the protrusions in the conductive particle 3 can be controlled, for example, by adjusting the concentration of the plating solution during the stepwise increase in the concentration of the plating solution in the metal plating process. For example, the area fraction of the protrusions can be increased by rapidly increasing the concentration of the plating solution to accelerate the reaction. Furthermore, for example, when the core is formed from resin, the compressive hardness of the conductive particles can be controlled by appropriately adjusting the type of resin (if the resin is a copolymer, the proportion of monomers to be copolymerized).

The conductive particles 3 having the protrusions described above can also be obtained, for example, by placing an insulating or conductive seed material on the surface of the core 31 and then forming the conductive layers 32A and 32B by metal plating. In this case, the area fraction of the protrusions in the conductive particles 3 can also be adjusted, for example, by varying the amount of the seed material placed on the surface of the core 31.

The content of the conductive particles 3 may be 5% by mass or more, 10% by mass or more, and may be 30% by mass or less, or 25% by mass or less, based on the total mass of solids in the adhesive composition.

The content of the conductive particles 3 may be 1% by volume or more, and may be 50% by volume or less, or 40% by volume or less, based on the total volume of solids in the adhesive composition.

The adhesive component 2 is composed of, for example, an insulating, heat- or light-curable material. The adhesive component 2 may contain a polymerizable substance having a radically polymerizable functional group. Examples of the polymerizable substance include (meth)acrylates.

Examples of the (meth)acrylates include (poly) urethane (meth)acrylate, methyl (meth)acrylate, ethyl (meth)acrylate, isopropyl (meth)acrylate, isobutyl (meth)acrylate, ethylene glycol diacrylate, diethylene glycol diacrylate, triethylene glycol diacrylate, dimethyloltricyclodecane diacrylate, trimethylolpropane triacrylate, tetramethylolmethane tetraacrylate, 2-hydroxy-1,3-diacryloxypropane, 2,2-bis [4-(acryloxymethoxy)phenyl]propane, 2,2-bis [4-(acryloxypolyethoxy)phenyl]propane, dicyclopentenyl acrylate, tricyclodecanyl acrylate, bis(acryloxyethyl) isocyanurate, ε-caprolactone-modified tris(acryloxyethyl) isocyanurate, tris(acryloxyethyl) isocyanurate, and ethylene oxide-modified phosphate di(meth)acrylate. When ethylene oxide-modified di(meth)acrylate phosphate is used as the (meth)acrylate, the adhesive composition has higher adhesive strength.

The adhesive component 2 may contain only a (meth)acrylate as the polymerizable substance, or may contain other polymerizable substances in addition to the (meth)acrylate. The polymerizable substance is a substance having a radically polymerizable functional group. Examples of other polymerizable substances include maleimide compounds.

The content of the polymerizable substance may be 10% by mass or more, 20% by mass or more, 30% by mass or more, or 40% by mass or more, and may be 80% by mass or less, 70% by mass or less, 60% by mass or less, or 50% by mass or less, based on the total mass of the adhesive component 2.

The adhesive component 2 may contain a curing agent (thermal radical polymerization initiator). The curing agent is a compound that decomposes upon heating to generate free radicals.

Examples of the curing agent include peroxides and azo compounds. Examples of peroxides include diacyl peroxides, such as dioctanoyl peroxide, dilauroyl peroxide, distearoyl peroxide, and dibenzoyl peroxide; peroxydicarbonates, such as bis(4-t-butylcyclohexyl) peroxydicarbonate, di-2-ethoxyethyl peroxydicarbonate, and di-2-ethylhexyl peroxydicarbonate; peroxyesters, such as t-butyl peroxypivalate, t-hexyl peroxypivalate, 1,1,3,3-tetramethylbutyl peroxy-2-ethylhexanoate, 2,5-dimethyl-2,5-di(2-ethylhexanoylperoxy) hexane, t-hexylperoxy-2-ethylhexanoate, t-butylperoxy-2-ethylhexanoate, t-butylperoxyisobutyrate, t-hexylperoxyisopropyl monocarbonate, t-butylperoxy-3,5,5-trimethylhexanoate, t-butyl peroxylaurate, t-butylperoxy-2-ethylhexyl monocarbonate, t-butyl peroxybenzoate, t-hexyl peroxybenzoate, 2,5-dimethyl-2,5-bis(benzoylperoxy) hexane, and t-butyl peroxyacetate; peroxyketals, such as 1,1-bis(t-butylperoxy)cyclohexane, 1,1-bis(t-butylperoxy)-2-methylcyclohexane, 1,1-bis(t-butylperoxy)-3,3,5-trimethylcyclohexane, 1,1-bis(t-hexylperoxy)cyclohexane, and 1,1-bis(t-hexylperoxy)-3,3,5-trimethylcyclohexane; dialkyl peroxides, such as dicumyl peroxide, t-butylcumyl peroxide, and di-t-butyl peroxide; and hydroperoxides, such as p-menthane hydroperoxide.

Examples of azo compounds include 2,2′-azobis(2, 4-dimethylvaleronitrile) and 2,2′-azobisisobutyronitrile.

As the curing agent, one of the peroxides and azo compounds described above may be used alone, or two or more thereof may be used in combination. The adhesive component preferably contains, as the curing agent, at least one of a diacyl peroxide and a peroxyester. The one-minute half-life temperature of the diacyl peroxide and the peroxy ester may each independently be 90° C. to 175° C. The molecular weight of the diacyl peroxide and the peroxy ester may each independently be 180 to 1000.

The content of the curing agent may be 0.05% by mass or more, 0.1% by mass or more, 1% by mass or more, or 2% by mass or more, and may be 20% by mass or less, 10% by mass or less, or 8% by mass or less, based on the total mass of the adhesive component 2.

The adhesive component 2 may contain a thermoplastic resin. Examples of the thermoplastic resin include polyamide resins, phenoxy resins, (meth)acrylic resins, polyimide resins, polyester resins, polyurethane resins, polyesterurethane resins, and polyvinyl butyral resins. These thermoplastic resins may be used alone, or may be used as a mixture of two or more.

The content of the thermoplastic resin may be 20% by mass or more, and may be 50% by mass or less, based on the total mass of the adhesive component 2.

The adhesive component 2 may further contain other components, such as a curing modifier, an adhesion promoter, a coupling agent (e.g., a silane coupling agent), an ion trapping agent, a visualizing agent, a dispersant, a photoradical polymerization initiator, and a filler. The content of these other components may be, for example, 1% by mass or more and 20% by mass or less based on the total mass of the adhesive component.

In other embodiments, the adhesive film may have two or more regions. The adhesive film may include a first region containing a first adhesive component and a second region formed adjacent to the first region and containing a second adhesive component. The first region and the second region may each be a layer.

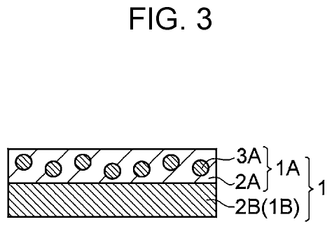

For example, as illustrated in FIG. 3, the adhesive film 1 may have a two-layer structure including a layer 1A containing conductive particles 3A (a first adhesive layer containing an adhesive component 2A and conductive particles 3A dispersed in the adhesive component 2A) and a layer 1B free of conductive particles (a second adhesive layer composed of an adhesive component 2B). In this case, the first adhesive layer 1A may contain the polymerizable substance, the curing agent, the curing modifier, the thermoplastic resin, and the conductive particles described above, and other components as necessary. The second adhesive layer 1B may contain the polymerizable substance, the curing agent, the curing modifier, and the thermoplastic resin described above, and other components as necessary. The components contained in the second adhesive layer 1B may be the same as those contained in the first adhesive layer 1A, or may be different.

The content of each of the polymerizable substance, the curing agent, the curing modifier, the thermoplastic resin, and other components in the first adhesive layer and the second adhesive layer may independently be similar to the content of that component in the adhesive composition described above. In this case, the phrase “based on the total mass of the adhesive component” is read as “based on the total mass of the adhesive component contained in the first adhesive layer” or “based on the total mass of the adhesive component contained in the second adhesive layer.”

The number density of the conductive particles 3 in the adhesive film 1 may be 1000 particles/mm² or more, 3000 particles/mm² or more, 5000 particles/mm² or more, 7000 particles/mm² or more, or 8000 particles/mm² or more, and may be 15000 particles/mm² or less, 13000 particles/mm² or less, 12000 particles/mm² or less, or 11000 particles/mm² or less. The number density of the conductive particles 3 is determined by counting the number of the conductive particles 3 per unit area of the adhesive film 1 using an electron microscope.

The thickness of the adhesive film 1 may be, for example, 5 μm or more, or 10 μm or more, and may be 50 μm or less, 30 μm or less, or 20 μm or less.

The adhesive composition (adhesive film 1) may be a conductive adhesive composition (conductive adhesive film) or an anisotropic conductive adhesive composition (anisotropic conductive adhesive film). The adhesive composition can be suitably used to produce a connection structure.

### <Connection Structure>

A connection structure according to an embodiment includes: a first electronic member having a first electrode; a second electronic member having a second electrode; and a connection portion disposed between the first electronic member and the second electronic member and electrically connecting the first electrode and the second electrode to each other. The connection portion contains a cured product of the adhesive composition described above.

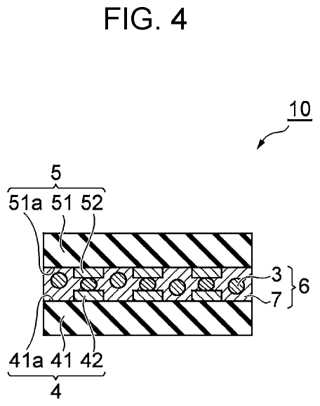

FIG. 4 is a schematic cross-sectional view of one embodiment of a connection structure. Referring to FIG. 4, a connection structure 10 includes: a first electronic member 4 and a second electronic member 5 facing each other; and a connection portion 6 disposed between the first electronic member 4 and the second electronic member 5 and connecting the first electronic member 4 and the second electronic member 5.

The first electronic member 4 includes a first substrate 41 and a first electrode 42 formed on a main surface 41a of the first substrate 41. The second electronic member 5 includes a second substrate 51 and a second electrode 52 formed on a main surface 51a of the second substrate 51.

The first electronic member 4 and the second electronic member 5 are not limited as long as they are members in which electrodes requiring electrical connection are formed. Examples of the members in which electrodes are formed include diodes, such as micro-OLEDs, active elements, such as semiconductor chips, transistors, and thyristors, passive elements, such as capacitors, resistors, and coils, and substrates equipped with electrodes, such as printed circuit boards.

The first substrate 41 and the second substrate 51 may be, for example, silicon substrates, glass substrates, or flexible substrates. The flexible substrates may contain, for example, at least one thermoplastic resin selected from the group consisting of polyimide (PI), polyethylene terephthalate (PET), polycarbonate (PC), and polyethylene naphthalate (PEN).

Examples of electrode materials for forming the first electrode 42 and the second electrode 52 include metals, such as Ag, Ni, Al, Au, Cu, Ti, and Mo; metal oxides, such as ITO and IZO; and conductors, such as silver nanowires and carbon nanotubes. The first electrode 42 and the second electrode 52 may be formed of the same material or of different materials.

In one embodiment, the first electrode 42 may include a base layer on the first substrate 41 and a surface layer on the base layer. In another embodiment, the second electrode 52 may include a base layer on the second substrate 51 and a surface layer on the base layer. These surface layers are located at the outermost surfaces of the first electrode 42 and the second electrode 52. Either the first electrode 42 or the second electrode 52 may include a base layer and a surface layer, or both the first electrode 42 and the second electrode 52 may include a base layer and a surface layer.

The base layer may contain, for example, a hard metal, such as Ni. The surface layer may contain, for example, a soft metal, such as Au or Pd. The surface layer may have a lower hardness than the base layer.

The thickness of the surface layer may be 0.005 μm or more, or 0.01 μm, and may be 5 μm or less, or 3 μm or less. Since the compressive hardness of the conductive particles and the area fraction of the protrusions of the conductive particles are within specific ranges in the adhesive film according to one embodiment, the contact area between the electrode and the adhesive film is sufficiently large, and the protrusions of the conductive particles easily indent into the electrode even when the electrode has a base layer formed of a hard metal and the surface layer is thin.

The first electronic member 4 and the second electronic member 5 may have one first electrode 42 and one second electrode 52, respectively, but preferably have a plurality of first electrodes 42 and a plurality of second electrodes 52 at predetermined intervals, respectively.

The connection portion 6 contains an insulating material 7, which is a cured product of the adhesive component, and the conductive particles 3. The conductive particles 3 may be disposed not only between the opposing first electrode 42 and second electrode 52 but also between the main surface 41a of the first substrate 41 and the main surface 51a of the second substrate 51. In the connection structure 10, the first electrode 42 and the second electrode 52 are electrically connected to each other with the conductive particle 3 interposed therebetween. In other words, the conductive particle 3 is in contact with both the first electrode 42 and the second electrode 52.

In the connection structure 10, as described above, the opposing first electrode 42 and second electrode 52 are electrically connected to each other with the conductive particle 3 interposed therebetween. This configuration sufficiently reduces the connection resistance between the first electrode 42 and the second electrode 52. It is thus possible to facilitate the flow of current between the first electrode 42 and the second electrode 52, allowing the first electronic member 4 and the second electronic member 5 to fully exhibit their respective functions.

### <Method for Producing Connection Structure>

The connection structure described above can be produced by a method including: a step of placing the adhesive composition between the first electronic member having the first electrode and the second electronic member having the second electrode; and a step of thermocompression-bonding the first electronic member and the second electronic member to each other with the adhesive composition interposed therebetween to electrically connect the first electrode and the second electrode to each other.

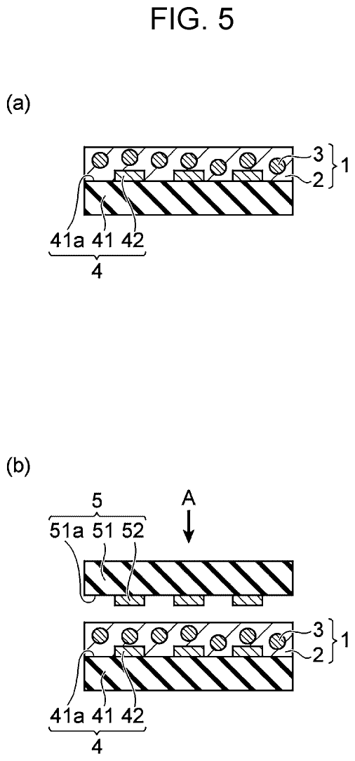

FIG. 5 includes schematic cross-sectional views of one embodiment of a method for producing the connection structure. As illustrated in FIG. 5 (a), first, the adhesive film 1 (a film-like adhesive composition) is placed on the main surface 41a of the first electronic member 4. If the adhesive film 1 is disposed on a substrate (not shown), the laminate of the substrate and the adhesive film 1 is placed on the first electronic member 4 such that the adhesive film 1 side of the substrate faces the first electronic member 4. When the adhesive film 1 has the first adhesive layer 1A and the second adhesive layer 1B as illustrated in FIG. 3, the adhesive film 1 is preferably placed such that the first adhesive layer 1A is in contact with the main surface 41a of the first electronic member 4 to increase the number of conductive particles captured between the opposing electrodes.

After the adhesive film 1 is placed on the main surface 41a of the first electronic member 4, the laminate of the adhesive film 1 and the first electronic member 4 may be pressed in the lamination direction to provisionally bond the adhesive film 1 to the first electronic member 4. In this case, heat may be applied during pressing.

Subsequently, as illustrated in FIG. 5 (b), the second electronic member 5 is further placed on the adhesive film 1 on the first electronic member 4 such that the second electrode 52 faces the first electronic member 4 (i.e., the first electrode 42 and the second electrode 52 are arranged so as to face each other, and the adhesive film 1 is placed between the first electronic member 4 and the second electronic member 5). When the adhesive film 1 is disposed on a substrate (not shown), the second electronic member 5 is placed on the adhesive film 1 after peeling the substrate off.

The first electronic member 4 and the second electronic member 5 are then thermocompression-bonded to each other with the adhesive film 1 interposed therebetween. The thermocompression bonding is performed, for example, by applying heat and pressure in the direction of arrow A in FIG. 5 (b). The adhesive film 1 cures under the heat and pressure applied in the direction of arrow A to electrically connect the first electrode 42 and the second electrode 52 to each other. As a result, the connection structure 10 as illustrated in FIG. 4 is obtained.

The pressure application during thermocompression bonding may be performed at, for example, 5 MPa or higher, or 20 MPa or lower. The heat application during thermocompression bonding may be performed at, for example, 100° C. or higher, 170° C. or lower, 150° C. or lower, or 130° C. or lower. The pressure application time and the heat application time during thermocompression bonding may be, for example, 10 seconds or longer, and may be 60 seconds or shorter.

In the connection structure 10 obtained as described above, the conductive particle 3 can come into contact with both the opposing first electrode 42 and second electrode 52, thereby sufficiently reducing the connection resistance between the first electrode 42 and the second electrode 52.

Upon application of both heat and pressure to the adhesive film 1, the adhesive component 2 cures to form the insulating material 7 while the first electrode 42 and the second electrode 52 are maintained at a sufficiently small spacing, thereby firmly connecting the first electronic member 4 and the second electronic member 5 to each other with the connection portion 6 interposed therebetween.

### EXAMPLES

The present invention will be described below in more detail by way of Examples. The present invention is not limited to these Examples.
<Preparation of Conductive Particles A1 to A8 and a1 to a4>

The conductive particles A1 to A8 and a1 to a4 were prepared as described below.

### Preparation of Conductive Particles A1

Tetramethylolmethane tetraacrylate, divinylbenzene, and styrene were used as monomers and polymerized by suspension polymerization using a polymerization initiator (benzoyl peroxide) to obtain cores (average particle size: 5.0 μm). The cores were subjected to electroless Ni plating to obtain conductive particles each having protrusions and a conductive layer formed of Ni (Ni layer, thickness: 60 nm). A layer formed of Pd (Pd layer, thickness: 10 nm) and having protrusions was formed on the Ni layer of the conductive particles by displacement plating to obtain conductive particles A1.

### Preparation of Conductive Particles A2

The cores (average particle size: 3 μm) were subjected to electroless Ni plating to obtain conductive particles A2 each having protrusions and a conductive layer formed of Ni (Ni layer, thickness: 120 nm).

### Preparation of Conductive Particles A3

The cores (average particle size: 3.25 μm) were subjected to electroless Ni plating to obtain conductive particles A3 each having protrusions and a conductive layer formed of Ni (Ni layer, thickness: 140 nm).

### Preparation of Conductive Particles A4

The surface of the cores (average particle size: 3 μm) was subjected to Ni—W—B plating to obtain conductive particles A4 each having protrusions and a conductive layer formed of Ni—W—B.

### Preparation of Conductive Particles A5

The surface of the cores (average particle size: 3 μm) was subjected to Pd plating to obtain conductive particles A5 each having protrusions and a conductive layer formed of Pd (Pd layer, thickness: 26 nm).

### Preparation of Conductive Particles A6

The cores (average particle size: 3 μm) were subjected to electroless Ni plating to obtain conductive particles A6 each having protrusions and a conductive layer formed of Ni (Ni layer).

### Preparation of Conductive Particles A7

The surface of the cores (average particle size: 3 μm) was subjected to Pd plating to obtain conductive particles A7 each having protrusions and a conductive layer formed of Pd (Pd layer, thickness: 24.4 nm).

### Preparation of Conductive Particles A8

The cores (average particle size: 5 μm) were subjected to electroless Ni plating to obtain conductive particles A8 each having protrusions and a conductive layer formed of Ni (Ni layer, thickness: 140 nm).

### Preparation of Conductive Particles a1

The cores (average particle size: 3 μm) were subjected to electroless Ni plating to obtain conductive particles a1 each having protrusions and a conductive layer formed of Ni (Ni layer, thickness: 110 nm).

### Preparation of Conductive Particles a2

The cores (average particle size: 3 μm) were subjected to electroless Ni plating to obtain conductive particles each having protrusions and a conductive layer formed of Ni (Ni layer). A layer formed of Pd (Pd layer) and having protrusions was formed on the Ni layer of the conductive particles by displacement plating to obtain conductive particles a2.

### Preparation of Conductive Particles a3

The surface of the cores (average particle size: 3 μm) was subjected to Ni—P plating to obtain conductive particles a3 each having protrusions and a conductive layer formed of Ni—P, wherein the protrusions had the area fraction and average height as shown in Table 1.

### Preparation of Conductive Particles a4

The cores (average particle size: 3.8 μm) were subjected to electroless Ni plating to obtain conductive particles a4 each having protrusions and a conductive layer formed of Ni (Ni layer, thickness: 120 nm).

<Analysis of Conductive Particles A1 to A8 and a1 to a4>

### (Area Fraction of Protrusions)

The conductive particles A1 to A8 and a1 to a4 were collected on their respective carbon tapes, and the collected conductive particles were imaged with a scanning electron microscope (SEM) to obtain SEM images each containing the corresponding conductive particles. These SEM images were analyzed using the method described in the section of Description of Embodiments to determine the area fraction of the protrusions of the conductive particles A1 to A8 and a1 to a4. The results are shown in Table 1.

### (Compressive Hardness at 20% Compression)

The compressive hardness of the conductive particles at 20% compression was determined using the following method. A microcompression tester (HM2000 manufactured by Fischer Instruments K.K.) was prepared, and the conductive particles were scattered onto a slide glass (S1214 manufactured by Matsunami Glass Ind., Ltd.) on a stage set at 25° C. One particle was then selected from the scattered conductive particles and compressed at a rate of 0.33 mN/s from the center from an initial load of 0.1 mN using a diamond indenter having a prismatic shape with a square base of 50 μm on a side to obtain the stress-strain curve. The load value at 20% deformation of the conductive particle size (at 20% compression) was read, and the compressive hardness of the conductive particle at 20% compression was calculated using the following equation. The results are shown in Table 1.

$$Compressive Hardness of Conductive Particle at 20 \% Compression = ( 3 / √ 2 ) \times {F}_{20} \times {S}_{20}^{- 3.2} \times {R}^{- 1 / 2} \times {10}^{- 3}$$

R: radius (μm) of conductive particle, S₂₀: displacement (mm) at 20% compression, F₂₀: load (N) at 20% compression

### Example 1

### (Synthesis of Polyurethane Acrylate (UA1))

To a reaction vessel having a stirrer, a thermometer, a reflux condenser provided with a calcium chloride drying tube, and a nitrogen-gas inlet tube, 2500 parts by mass (2.50 mol) of poly(1,6-hexanediol carbonate) (product name: Duranol T5652, manufactured by Asahi Kasei Chemicals Corporation, number-average molecular weight 1000) and 666 parts by mass (3.00 mol) of isophorone diisocyanate (manufactured by Sigma-Aldrich) were uniformly added dropwise over 3 hours. Next, the reaction vessel was thoroughly purged with nitrogen gas, and the inside of the reaction vessel was heated to 70° C. to 75° C. to allow the reaction to proceed. Subsequently, 0.53 parts by mass (4.3 mmol) of hydroquinone monomethyl ether (manufactured by Sigma-Aldrich) and 5.53 parts by mass (8.8 mmol) of dibutyltin dilaurate (manufactured by Sigma-Aldrich) were added to the reaction vessel, and 238 parts by mass (2.05 mol) of 2-hydroxyethyl acrylate (manufactured by Sigma-Aldrich) was added, and the mixture was allowed to react in an air atmosphere at 70° C. for 6 hours. This yielded polyurethane acrylate (UA1). The weight-average molecular weight of polyurethane acrylate (UA1) was 15,000. The weight-average molecular weight was measured by gel permeation chromatography (GPC) using a standard polystyrene calibration curve under the following conditions.

### (Measurement Conditions)

Apparatus: GPC-8020 manufactured by Tosoh Corporation
Detector: RI-8020 manufactured by Tosoh Corporation
Column: Gelpack GLA160S+GLA150S, Resonac Techno Service Corp.
Sample concentration: 120 mg/3 mL
Solvent: Tetrahydrofuran
Injection volume: 60 μL
Pressure: 2.94×10⁶ Pa (30 kgf/cm²)
Flow rate: 1.00 mL/min

### (Method for Preparing Polyester Urethane Resin)

To a heater-equipped stainless steel autoclave having a stirrer, a thermometer, a condenser, a vacuum generator, and a nitrogen gas inlet tube, 48 parts by mass of isophthalic acid and 37 parts by mass of neopentyl glycol were added, and 0.02 parts by mass of tetra-butoxy titanate was further added as a catalyst. Next, under a nitrogen gas flow, the resulting mixture was heated to 220° C. and stirred at that temperature for 8 hours. The pressure was then reduced to atmospheric pressure (760 mmHg), and the mixture was cooled to room temperature. As a result, a white precipitate was deposited. Next, the white precipitate was collected, washed with water, and vacuum-dried to obtain a polyester polyol. The obtained polyester polyol was thoroughly dried, then dissolved in MEK (methyl ethyl ketone), and introduced into a four-neck flask having a stirrer, a dropping funnel, a reflux condenser, and a nitrogen gas inlet tube. Additionally, dibutyltin dilaurate was added as a catalyst in an amount of 0.05 parts by mass per 100 parts by mass of the polyester polyol. Furthermore, 50 parts by mass of 4,4′-diphenylmethane diisocyanate per 100 parts by mass of the polyester polyol was dissolved in MEK and added via the dropping funnel, and the mixture was stirred at 80° C. for 4 hours to yield a polyester urethane resin.

### Preparation of First Adhesive Composition

17 parts by mass of dimethylol tricyclodecane diacrylate (product name: DCP-A, manufactured by Kyoeisha Chemical Co., Ltd.), 30 parts by mass of the polyurethane acrylate synthesized as described above, and 1.5 parts by mass of ethylene oxide-modified phosphoric acid dimethacrylate (product name: PM-21, manufactured by Nippon Kayaku Co., Ltd.) serving as polymerizable substances; 2.5 parts by mass of 2,5-dimethyl-2,5-di(2-ethylhexanoylperoxy) hexane (product name: Perhexa 250, manufactured by NOF Corporation) serving as a curing agent; 45 parts by mass of the polyester urethane resin prepared as described above and serving as a thermoplastic resin; 2.8 parts by mass of 3-glycidoxypropyltrimethoxysilane (product name: SH-6040, manufactured by Toray Dow Corning Co., Ltd.) serving as a silane coupling agent; 2.5 parts by mass of AEROSIL (product name: MR-202, manufactured by Nippon Aerosil Co., Ltd.) serving as a filler; and 26 parts by mass of the conductive particles A1 prepared by the above method were mixed to obtain a first adhesive composition. The content of the conductive particles was 4% by volume based on the total volume of the first adhesive composition.

### Preparation of Second Adhesive Composition

30 parts by mass of dimethylol tricyclodecane diacrylate (product name: DCP-A, manufactured by Kyoeisha Chemical Co., Ltd.), 27.5 parts by mass of the polyurethane acrylate synthesized as described above, and 2.5 parts by mass of ethylene oxide-modified phosphoric acid dimethacrylate (product name: PM-21, manufactured by Nippon Kayaku Co., Ltd.) serving as polymerizable substances; 5.0 parts by mass of 2,5-dimethyl-2,5-di(2-ethylhexanoylperoxy) hexane (product name: Perhexa 250, manufactured by NOF Corporation) serving as a curing agent; 27.5 parts by mass of the polyester urethane resin prepared as described above and 15 parts by mass of a phenoxy resin (product name: Phenotohto ZX-1356-2, Nippon Steel Chemical & Material Co., Ltd.) serving as thermoplastic resins; 5 parts by mass of 3-glycidoxypropyltrimethoxysilane (product name: SH-6040, manufactured by Toray Dow Corning Co., Ltd.) serving as a silane coupling agent; and 8 parts by mass of AEROSIL (product name: R-202, manufactured by Nippon Aerosil Co., Ltd.) serving as a filler were mixed to obtain a second adhesive composition.

A first adhesive layer was formed by applying the first adhesive composition to a substrate (a PET film with a thickness of 50 μm) using an applicator. A second adhesive layer was formed using the second adhesive composition in the same manner as the first adhesive layer. Furthermore, the first adhesive layer and the second adhesive layer were laminated together using a laminator to prepare an adhesive film (thickness: 14 μm).

### (Measurement of Number Density)

The number density of the conductive particles in the adhesive film was determined by counting the number of the conductive particles per mm² in the prepared adhesive film using an electron microscope. The results are shown in Table 1.

### Preparation of Electronic Members

The following electronic members were prepared.
Glass member

A glass member including a glass substrate and Ti/Al/Ti wiring formed on the glass substrate was prepared. The thickness of the glass substrate is 0.7 mm, and the wiring on the glass member has a line width of 300 μm and an electrode height of 750 nm.
Flexible printed circuit board (FPC)

An FPC including a resin film substrate containing polyethylene terephthalate (PET) as a base material and wiring on the resin film substrate was prepared. The wiring of the FPC has electrodes composed of a Cu layer at a pitch of 70 μm (35-μm space, 35-μm electrode width, 18-μm thickness) and a 0.5-μm-thick Ni layer and a 2.5 μm-thick Au layer formed in this order on the Cu layer.

### Preparation of Connection Structure

The adhesive film was placed on the glass member, and the FPC was then placed on the adhesive film to prepare a laminate including the glass member, the adhesive film, and the FPC. At this time, the main surface (the surface with the wiring formed thereon) of the glass substrate was positioned so as to face the main surface (the surface with the wiring formed thereon) of the resin film substrate. The adhesive film was placed such that the first adhesive layer of the adhesive film was in contact with the glass member. A cushion material made of silicone rubber was disposed on the FPC-side surface of the prepared laminate, and heat and pressure were applied through the cushion material using a thermocompression bonding device (heating method: pulse heat type, manufactured by Ohashi Seisakusho Co., Ltd.) to prepare a connection structure. The heating temperature was 120° C., the applied pressure was 14 MPa, and both the heating time and the pressing time were 30 seconds. The heating temperature refers to the set temperature of the thermocompression bonding device, and the applied pressure refers to the pressure over the total connection area.

(Connection Reliability under High-Temperature, High-Humidity Conditions)

The obtained connection structure was subjected to a reliability test at 85° C. and 85% RH. Specifically, first, the initial connection resistance between the electrode of the glass member and the electrode of the FPC in the connection structure was measured by the four-terminal method using a digital multimeter. Subsequently, the connection structure was left to stand in an environment at a temperature of 85° C. and a humidity of 85% RH for 100 hours, and the connection resistance (connection resistance after 100 h) was then measured using the same method as for the initial connection resistance. The connection resistance increase rate was calculated using the following equation. The results are shown in Table 1.

$$Connection resistance increase rate ( \% ) = \{ connection resistance after 100 h - initial connection resistance ) / initial connection resistance \} \times 100$$

### Examples 2 to 8 and Comparative Examples 1 to 4

Adhesive films and connection structures were prepared as in Example 1, except that, in place of the conductive particles A1, an equal amount of each of the conductive particles A2 to A8 and a1 to a4 prepared by the above method was used, and connection reliability was investigated. The results are shown in Table 1.

TABLE 1

| | | | Compressive | | | | |
|---|---|---|---|---|---|---|---|
| | | Area | hardness | Number | Initial | Connection | Connection |
| | Type of | fraction (%) | (kgf/mm²) | density | connection | resistance | resistance |
| | conductive | of | at 20% | (particles/ | resistance | (Ω) after | increase |
| | particles | protrusions | compression | mm²) | (Ω) | 100 h | rate (%) |
| Example 1 | A1 | 60 | 365 | 4000 | 0.940 | 1.435 | 53 |
| Example 2 | A2 | 30 | 396 | 6000 | 0.875 | 1.335 | 53 |
| Example 3 | A3 | 50 | 407 | 5000 | 0.575 | 1.125 | 96 |
| Example 4 | A4 | 50 | 431 | 10000 | 0.715 | 1.295 | 81 |
| Example 5 | A5 | 40 | 491 | 10000 | 0.815 | 0.965 | 18 |
| Example 6 | A6 | 40 | 572 | 8000 | 0.853 | 1.410 | 65 |
| Example 7 | A7 | 40 | 741 | 8000 | 0.913 | 1.233 | 35 |
| Example 8 | A8 | 50 | 1035 | 12000 | 0.975 | 1.515 | 55 |
| Comparative | a1 | 50 | 232 | 9000 | 0.745 | 2.195 | 195 |
| Example 1 | | | | | | | |
| Comparative | a2 | 60 | 345 | 10000 | 0.460 | 2.135 | 364 |
| Example 2 | | | | | | | |
| Comparative | a3 | 20 | 401 | 6000 | 1.135 | 3.240 | 185 |
| Example 3 | | | | | | | |
| Comparative | a4 | 60 | 2009 | 5000 | 2.895 | 4.720 | 63 |
| Example 4 | | | | | | | |

### REFERENCE SIGNS LIST

1: adhesive film, 1A: first adhesive layer, 1B: second adhesive layer, 2, 2A, 2B: adhesive component, 3, 3A, 30A, 30B: conductive particle, 4: first electronic member, 5: second electronic member, 6: connection portion, 7: insulating material, 10: connection structure, 31: core, 32A, 32B: conductive layer, 32a: first conductive layer, 32b: second conductive layer, 33, 33A, 33B: protrusion, 41: first substrate, 42: first electrode, 51: second substrate, 52: second electrode

1. A functional coating material comprising a curable component, a polysiloxane compound having an amino group, and a polymerization inhibitor.

2. The functional coating material according to claim 1, wherein the curable component is a photocurable resin composition.

3. The functional coating material according to claim 1, wherein the curable component is a thermosetting resin composition.

4. The functional coating material according to claim 1, wherein the polysiloxane compound having an amino group has an amine equivalent of 500 to 5000 g/mol.

5. The functional coating material according to claim 1, wherein the polymerization inhibitor is a catechol compound.

6. The functional coating material according to claim 1, wherein the polymerization inhibitor is an aminoxyl compound.

7. The functional coating material according to claim 1, which is a hard coating material.

8. A hard coating consisting of a cured product of the functional coating material according to claim 1.

9. The hard coating according to claim 8, wherein the haze is 2 or less.

10. A structure comprising a substrate and the hard coating according to claim 8 provided on the substrate.
